(19) United States
(12) Patent Application Publication
(10) Pub. No.: US 2007/0045778 A1
(43) Pub. Date: Mar. 1, 2007

(54) Wafer holder, heater unit used for wafer prober having the wafer holder, and wafer prober having the heater unit

(76) Inventors: Katsuhiro Itakura, Itami-shi (JP); Masuhiro Natsuhara, Itami-shi (JP); Tomoyuki Awazu, Itami-shi (JP); Hirohiko Nakata, Itami-shi (JP)

Correspondence Address: MCDERMOTT WILL & EMERY LLP, 600 13TH STREET, N.W., WASHINGTON, DC, 20005-3096, US

(21) Appl. No.: 11/498,988

(22) Filed: Aug. 4, 2006

(30) Foreign Application Priority Data
Aug. 5, 2005 (JP) 2005-227334 (P)

(51) Int. Cl. H01L 29/06

(52) U.S. Cl. 257/619

(57) ABSTRACT

A wafer holder for a wafer prober, a heater unit including the same, and a wafer prober including the heater unit are provided in which deformation or breakage of a chuck top can be prevented and proper measurement can be realized even in repeated use. A wafer holder in the present invention includes a chuck top having a chuck top conductive layer on a surface thereof and a support body supporting the chuck top. The chuck top and the support body are fixed to each other by a screw. The difference of thermal expansion coefficient between the screw and the chuck top is 5.0×10⁻⁶/K or less.

### BACKGROUND OF THE INVENTION

1. Field of the Invention

The present invention relates to a wafer holder for use in a wafer prober for inspecting the electric characteristics of a wafer by placing a semiconductor wafer on a wafer-placing surface and pressing a probe card against the wafer, a heater unit for a wafer prober including the wafer holder, and a wafer prober including the heater unit.

2. Description of the Background Art

Conventionally, in a semiconductor testing step, a heating process is performed on a semiconductor substrate (wafer) as a process target. Here, a burn-in step is performed in which a wafer is heated to a temperature higher than a normally used temperature to accelerate a defect in a semiconductor chip that is potentially defective for removal in order to prevent a defective after shipment. In this burn-in step, before a semiconductor wafer having circuits formed therein is cut into individual chips, the electric performance of each chip is determined while the wafer is heated, thereby removing a defective. In this burn-in step, reduction of the process time is strongly requested in order to improve a throughput.

In such a burn-in step, a heater for holding a semiconductor substrate and heating the semiconductor substrate is used. The conventionally used heater is made of a metal since the entire back surface of a wafer should be brought into contact with a ground electrode. A wafer having circuits formed therein is placed on a metal flat plate heater in order to determine the electric characteristics of a chip. In determination, a determiner called a probe card including a number of electrode pins for supplying power is pressed against a wafer at a force of a few tens of kgf to a few hundreds of kgf. Therefore, if the heater is thin, the heater is deformed, possibly resulting in poor contact between a wafer and a probe pin. Thus, for the purpose of keeping the rigidity of the heater, a thick metal plate of 15 mm or thicker has to be used, which requires long time to increase and decrease the temperature of the heater and thus hinders improvement of throughput.

Moreover, in the burn-in step, the electric characteristics are determined by feeding current to a chip. With higher power of recent chips, chips generate much heat during determination of electric characteristics. In some cases, chips may be failed due to the generated heat from itself Therefore, chips need to be cooled rapidly after determination. In addition, thermal uniformity is required during determination. Then, copper (Cu) having high thermal conductivity of 403W/mK has been used as a material of the metal.

Then, Japanese Patent Laying-Open No. 2001-033484 proposes a wafer prober which is less likely to be deformed and having small heat capacity, in which, in place of a thick metal plate, a thin metal layer is formed on a surface of a ceramic substrate which is thin but highly rigid and less likely to be deformed. According to this document, the high rigidity prevents poor contact, and the small heat capacity enables the temperature rise and drop for a short time. In addition, an aluminum alloy, stainless steel or the like may be used for a support base for installing a wafer prober.

However, as disclosed in Japanese Patent Laying-Open No. 2001-033484, when the wafer prober is supported only with the outermost circumference thereof, the pressure of the probe card may cause the wafer prober to be warped. Therefore, any technique such as provision of a number of pillars or the like is required.

Furthermore, recently, with miniaturization in semiconductor processes, the load per unit area in probing is increased and in addition, the accuracy of registration between a probe card and a prober is required. The prober usually repeats an operation of heating a wafer at a prescribed temperature, moving to a prescribed position in probing, and pressing a probe card. Here, high positional accuracy is also required of a driving system for moving the prober to a prescribed position.

However, when a wafer is heated to a prescribed temperature, that is, a temperature of about 100-200° C., the heat is transferred to the driving system, causing thermal expansion of metal parts of the driving system, resulting in deteriorated accuracy. Furthermore, with the increased load in probing, the rigidity of the prober itself on which a wafer is placed is also demanded. In other words, if the prober itself is deformed by the load in probing, the pin of the probe card cannot contact with a wafer uniformly, thereby to make the testing impossible. At worst, a wafer is broken. Therefore, in order to prevent deformation of the prober, the prober is increased in size and weight. The increased weight affects the accuracy of the driving system. In addition, with the increased size of the prober, the time required to increase and cool the temperature of the prober becomes extremely long, thereby reducing throughput.

Moreover, in order to improve the speed of increasing and decreasing the temperature of the prober to improve throughput, a cooling mechanism is often provided. However, a conventional cooling mechanism, for example, provides air cooling as disclosed in Japanese Patent Laying-Open No. 2001-033484 or is provided with a cold plate immediately below a metal heater. In the case of the former, the cooling speed is slow due to air cooling. On the other hand, in the case of the latter, the cold plate is made of a metal and the pressure of the probe card is directly applied to this cold plate in probing, so that the cold plate is easily deformed.

The prober is under a load at the chuck top because of the stress exerted in probing, causing deformation. If this deformation results in significant bending, the contact state between a number of probe pins attached to the probe card and a wafer varies to cause an error in determination and make it impossible to make proper evaluations.

Japanese Patent Laying-Open No. 2001-319964 also discloses a method of installing a ceramic substrate used for a semiconductor tester to a support container. In this technique, the substrate is fixed at the end portion thereof to the support container by a technique such as screwing. Therefore, the temperature of the end portion of the substrate fixed by screwing is decreased, so that the uniformity of temperature of the wafer-placing surface of the ceramic substrate is inevitably degraded.

### SUMMARY OF THE INVENTION

The present invention is made to solve the aforementioned problems. It is an object of the present invention to provide a wafer holder, a heater unit for a wafer prober including the wafer holder, and a wafer prober including the heater unit, in which deformation and breakage of a chuck top can be prevented, and proper measurement can be realized even in the repeated use.

A wafer holder in accordance with the present invention includes a chuck top having a chuck top conductive layer on a surface thereof and a support body supporting the chuck top. The chuck top and the support body are fixed to each other by a screw, and a difference of thermal expansion coefficient between the screw and the chuck top is at most 5.0×10⁻⁶/K.

In another aspect, a wafer holder in accordance with the present invention includes a chuck top having a chuck top conductive layer on a surface thereof, a support body supporting the chuck top, and a cooling mechanism for cooling the chuck top. The chuck top and the support body and the cooling mechanism are fixed to each other by a screw. A thermal expansion coefficient of the screw is between a thermal expansion coefficient of the chuck top and a thermal expansion coefficient of the cooling mechanism.

Preferably, the aforementioned screw is arranged in the form of a concentric circle including a central portion of the chuck top. Preferably, the aforementioned screw is fixed in a screw hole formed in the chuck top using heat resistant resin.

A heater unit for a wafer prober includes the wafer holder as described above, and a wafer prober includes the heater unit.

In accordance with the present invention, breakage or deformation of the chuck top can be prevented even in the repeated use by controlling the thermal expansion coefficient of a screw fixing the chuck top with the support body and a screw fixing the cooling mechanism to the chuck top. In addition, it is possible to provide a wafer holder excellent in thermal uniformity as compared with the conventional, a heater unit including the wafer holder, and a wafer prober including the heater unit.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows an exemplary cross sectional structure of a wafer holder in accordance with the present invention.

FIG. 2 shows an exemplary cross sectional structure of a wafer holder in accordance with the present invention.

### DESCRIPTION OF THE PREFERRED EMBODIMENTS

In the following, an embodiment of the present invention will be described with reference to the figures. It is noted that in the following drawings, the same or corresponding parts will be denoted with the same reference characters and description thereof will not be repeated.

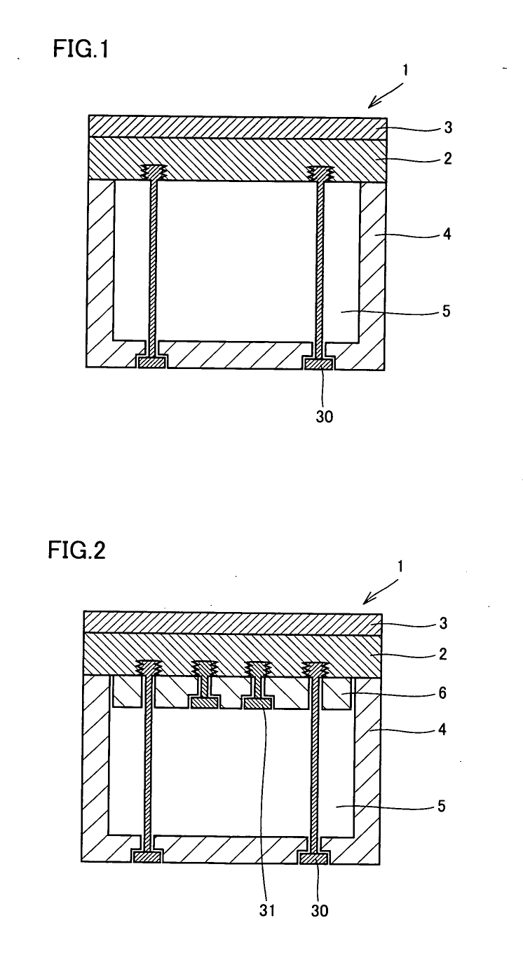

An embodiment of the present invention will be described with reference to FIG. 1. FIG. 1 shows an exemplary embodiment of the present invention. In the embodiment, a wafer holder 1 for a wafer prober is taken as an example of the wafer holder in accordance with the present invention. Wafer holder 1 in accordance with the present invention includes a chuck top 2 having a chuck top conductive layer 3 and a support body 4 supporting chuck top 2 and has a cavity 5 at a part between chuck top 2 and support body 4. Chuck top 2 and the support body are fixed to each other by a screw 30.

A plurality of screw holes for inserting screws 30 are formed on the surface of chuck top 2, which chuck top 2 serves as a main body of wafer holder 1, on the support body side. A plurality of through holes through which screws 30 are inserted are formed in support body 4. Screw 30 is inserted through the through hole and screwed into the screw hole formed in chuck top 2, whereby chuck top 2 and support body 4 are fixed to each other.

The difference between the thermal expansion coefficient of screw 30 and the thermal expansion coefficient of chuck top 2 and support body 4 is set at 5.0×10⁻⁶/K or less. When probing is conducted by placing a wafer on chuck top 2, the chuck top is normally heated at 100 to 200° C. Here, chuck top 2 has a thermal expansion amount corresponding to the temperature. As a matter of course, screw 30 for fixing which is inserted in chuck top 2 also expands. However, if the amount of the expansion is considerably larger than that of chuck top 2, that thermal expansion amount causes chuck top 2 to be deformed or broken.

It is noted that in the present invention, the thermal expansion coefficient may be measured, for example, by a laser interferometric method or TMA (Thermo Mechanical Analysis) method.

On the other hand, if the thermal expansion coefficient of screw 30 is considerably smaller, stress is exerted on the thread formed in chuck top 2 or the thread formed on the screw itself and may cause the thread to be broken. Therefore, it is necessary that the difference between the thermal expansion coefficient of the screw screwed into chuck top 2 and the thermal expansion coefficient of the chuck top should be 5.0×10⁻⁶/K or less.

Furthermore, the screw for fixing is finally installed at the base portion of the support body. Here, support body 4 itself also receives heat from chuck top 2 and expands in the horizontal direction in FIG. 1. Screw 30 also expands in the same direction. Screw 30 is in contact with support body 4 on the support body side. Therefore, if the thermal expansion coefficient of support body 4 is larger than the thermal expansion coefficient of screw 30 by more than 5.0×10⁻⁶/K, undesirably, a great stress is exerted on the fixing portion of screw 30 with support body 4, so that screw 30 is broken or on the contrary, the support body is broken or deformed. Therefore, it is necessary for screw 30 to be used that the thermal expansion coefficient difference from chuck top 2 and support body 4 should be 5.0×10⁻⁶/K or less. Furthermore, a through hole is formed in support body 4 and a clearance is preferably formed between the through hole and screw 30 in consideration of the thermal expansion amount of chuck top 2. If such a clearance is not formed, the chuck top expands in the horizontal direction, and the screw is also pulled in a prescribed direction and expanded. If the clearance of support body 4 is small, undesirably, the through hole of support body 4 may be broken by the inserted screw.

As shown in FIG. 2, a screw 31 for fixing a cooling mechanism 6 to chuck top 2 preferably has a thermal expansion coefficient between the thermal expansion coefficient of chuck top 2 and the thermal expansion coefficient of cooling mechanism 6. Cooling mechanism 6 attached to chuck top 2 thermally expands in the horizontal direction in heating chuck top 2. However, during cooling, chuck top 2 has a temperature of 100-200° C. while cooling mechanism 6 has room temperature or lower. In this case, if the thermal expansion coefficient of screw 31 is larger than the thermal expansion coefficient of cooling mechanism 6, undesirably, screw 31 at the fixing portion may become loose, and if it is loose, the speed of cooling chuck top 2 is significantly reduced. On the other hand, if the thermal expansion coefficient of screw 31 is smaller than that of chuck top 2, on the contrary, screw 31 undesirably becomes loose in chuck top 2. It is noted that screw 30 fixing chuck top 2 and support body 4 also preferably has a thermal expansion coefficient between the thermal expansion coefficient of chuck top 2 and the thermal expansion coefficient of cooling mechanism 6. The thermal expansion coefficient of screws 30, 31 may also be equal to the thermal expansion coefficient of chuck top 2 and the thermal expansion coefficient of cooling mechanism 6. FIG. 2 shows an exemplary embodiment of the present invention.

Essentially, such cooling mechanism 6 needs to be brought into intimate contact with chuck top 2. Therefore, the thermal expansion coefficient of screw 31 should be controlled as described above. Cooling mechanism 6 is in intimate contact with chuck top 2 during heating and therefore the thermal expansion amount is that of the case where its temperature is increased to the same temperature. Thus, if a thermal expansion coefficient difference exists between chuck top 2 and cooling mechanism 6, the difference in thermal expansion amount between chuck top 2 and cooling mechanism 6 needs to be absorbed. In addition, during cooling, an extremely large difference of thermal expansion amount takes place between cooling mechanism 6 and chuck top 2. Thus, the through hole in cooling mechanism 6 through which screw 31 passes needs to have such a size that can absorb the difference of thermal expansion with screw 31.

The screw holes formed in chuck top 2 are preferably arranged in the form of a concentric circle including the central portion of chuck top 2. In this arrangement, preferably, support body 4 and chuck top 2 and/or cooling mechanism 6 and chuck top 2 can be fixed to each other uniformly.

Screws 30, 31 inserted into chuck top 2 are preferably fixed by heat resistant resin. When heat cycle is applied to chuck top 2 including screws 30, 31, screws 30, 31 may become loose. In order to prevent this, screws 30, 31 are suitably fixed to the screw holes by heat resistant resin. The heat resistant resin may include imide-base resins, phenol-base resins, epoxy-base resins, silicone-base resins, or ester-base resins, although not specifically limited thereto.

In the present invention, chuck top 2 is fixed from the bottom of support body 4 using a screw for fixing. In other words, chuck top 2 is fixed at the part other than the end portion thereof using a screw. Therefore, as compared with the conventional technique, the thermal uniformity of chuck top 2 is not degraded by the escape of heat from chuck top 2. More specifically, at the end portion of chuck top 2, a heating element does not exist in proximity, and therefore, if a fixing member such as a screw exists there, heat is transferred to the screw thereby reducing the temperature in proximity thereto. By contrast, in the present invention, a screw is inserted from the bottom of support body 4 and thus a heating element exists in proximity to the screw in chuck top 2. Therefore, a temperature drop is small. In addition, since chuck top 2 is fixed from the bottom, even if the temperature drops in proximity to the screw portion, the heat generated in the heating element diffuses toward the wafer-placing surface of chuck top 2 because of the thickness of chuck top 2. Therefore, a temperature drop at the surface of chuck top 2 is not caused in such an extent that thermal uniformity is degraded.

It is noted that in the present invention, “wafer-placing surface” refers to the surface of chuck top conductive layer 3 in chuck top 2.

Chuck top 2 preferably includes a heater body. This is because in the recent semiconductor probing, a wafer often needs to be heated at a temperature of 100-200° C. Therefore, if transmission of heat of the heater body heating the chuck top to support body 4 cannot be prevented, the heat is transferred to the driving system provided below the support body of the wafer prober, and the thermal expansion difference between the parts causes deviation of mechanical accuracy, which may result in significantly deteriorated flatness and parallelism of the top face (wafer-placing surface) of chuck top 2. However, since the present structure is thermally insulating, the flatness and parallelism are not significantly degraded. In addition, because of the hollow structure, weight reduction can be achieved as compared with the cylindrical shaped support body.

Preferably, the heater body is simply configured such that a resistance heating element is sandwiched between insulators such as mica. A metal material may be used for the resistance heating element. For example, a metal foil made of nickel, stainless steel, silver, tungsten, molybdenum, chrome, and an alloy of these metals can be used. Among these metals, stainless steel and nichrome are preferable. When processed into the shape of the heating element, stainless steel and nichrome can form the circuit pattern of the resistance heating element relatively accurately by etching or any other technique. Preferably, stainless steel and nichrome are cheap and resistant to oxidation so that they are likely to endure prolonged use even when used at a high temperature. Moreover, the insulators between which the resistance heating element is sandwiched are not specifically limited as long as they are heat-resistant. For example, as described above, mica, silicone resin, epoxy resin, phenol resin, or the like may be used. Furthermore, when the resistance heating element is sandwiched between such insulative resins, a filler can be dispersed in the resin in order to transfer the heat generated in the heating element to chuck top 2 more smoothly. The filler dispersed in the resin serves to increase the heat conduction of silicone resin or the like. A material of the filler is not specifically limited as long as it is not reactive with the resin and may include, for example, boron nitride, aluminum nitride, alumina, or silica. The heater body can be fixed to its installation part by a mechanical technique such as screwing.

Preferably, Young's modulus of support body 4 is 200 GPa or more. If Young's modulus of support body 4 is less than 200 GPa, the thickness of the base portion cannot be reduced and thus the volume of the cavity portion cannot be secured enough. Therefore, the heat-insulation effect cannot be expected. In addition, the space in which a cooling module described later is provided cannot be reserved. More preferable Young's modulus is 300 GPa or more. In particular, when a material having Young's modulus of 300 GPa or more is used, deformation of support body 4 is considerably reduced, so that further miniaturization and weight reduction of support body 4 are preferably achieved.

It is noted that in the present invention, Young's modulus can be measured, for example, by a pulse method, a bending resonance method, or the like.

Preferably, the thermal conductivity of support body 4 is 40 W/mK or less. If the thermal conductivity of support body 4 exceeds 40 W/mK, the heat applied to chuck top 2 is easily transferred to support body 4, which may undesirably affect the accuracy of the driving system. Recently, a high temperature of 150° C. is requested in probing. Therefore, the thermal conductivity of support body 4 is more preferably 10 W/mK or less. More preferably, the thermal conductivity is 5 W/mK or less. With the thermal conductivity in such an extent, the amount of heat transmission from support body 4 to the driving system is significantly reduced. A specific material of support body 4 to satisfy these conditions is preferably mullite, alumina, or a composite of mullite and alumina (mullite-alumina composite). Mullite is preferable in that the thermal conductivity is small and the heat-insulation effect is high. Alumina is preferable in that Young's modulus is large and the rigidity is high. Mullite-alumina composite is generally preferable in that the thermal conductivity is smaller than that of alumina and Young's modulus is larger than that of mullite.

It is noted that in the present invention, the thermal conductivity can be measured, for example, by a laser flash method or the like using a sliced pellet.

Preferably, the thickness of the cylindrical portion of support body 4 shaped like a cylinder with a base is 20 mm or less. If the thickness exceeds 20 mm, the amount of heat transmission from chuck top 2 to support body 4 undesirably increases. Therefore, the thickness of the cylindrical portion of support body 4 that supports chuck top 2 is preferably 10 mm or less. However, if the thickness is less than 1 mm, in testing a wafer, the pressure to press a probe card against a wafer unfortunately causes the cylindrical portion of support body 4 to be deformed or damaged at worst. The most preferable thickness is from 10 mm to 15 mm. In addition, the thickness of that portion of the cylindrical portion which is in contact with chuck top 2 is preferably 2 mm to 5 mm. The thickness in such an extent is preferable since the strength and the heat insulation of support body 4 are well balanced.

Preferably, the height of the cylindrical portion of support body 4 is 10 mm or more. If less than 10 mm, the pressure from the probe card is applied to chuck top 2 and additionally transferred to support body 4 during wafer testing. Therefore, the base portion of support body 4 may be bent thereby undesirably deteriorating the flatness of chuck top 2.

Preferably, the thickness of the base portion of support body 4 is 10 mm or more. If the thickness of the base portion of support body 4 is less than 10 mm, the base portion of support body 4 may be bent thereby undesirably deteriorating the flatness of chuck top 2, since the pressure from the probe card is applied to chuck top 2 and additionally transferred to support body 4 during wafer testing. Then, 10 mm to 35 mm is preferable. If 35 mm or less, miniaturization can suitably be achieved. Alternatively, the cylindrical portion and the base portion of support body 4 may not be integrated but may be separated. In this case, the separated cylindrical portion and base portion have an interface therebetween. This interface serves as a heat resistance layer, so that the heat transferred from chuck top 2 to support body 4 is blocked at this interface. Accordingly, preferably, the temperature of the base portion is less likely to be increased.

Preferably, a heat insulating structure is provided at the supporting surface of support body 4 which supports chuck top 2. Here, the heat insulating structure may be formed, for example, by forming a notch groove at support body 4 to reduce the contact area between chuck top 2 and support body 4. The heat insulating structure may also be formed by forming a notch groove at chuck top 2. In this case, it is necessary that Young's modulus of chuck top 2 should be 250 GPa or more. More specifically, the pressure of the probe card is applied to chuck top 2, so that with a material having small Young's modulus, the amount of deformation is inevitably increased in the presence of a notch groove. Then, the increased amount of deformation may lead to damage to a wafer and damage to chuck top 2 itself However, a notch is preferably formed at support body 4 to prevent the aforementioned problem. The shape of the notch is not specifically limited and may include, for example, a concentrically-arranged groove, a radially-arranged groove, a groove provided with a number of protrusions, or the like. It is noted that in any shape, the shape should be symmetric. If the shape is not symmetric, the pressure applied to chuck top 2 cannot be distributed uniformly, which may have an effect of deformation or damage of chuck top 2.

In addition, as another form of the heat insulating structure, a plurality of pillar-like members are preferably installed between chuck top 2 and support body 4. Here, eight or more pillar-like members are preferably arranged evenly in a concentric manner or any manner similar thereto. Since the size of a wafer has recently been increased such as 8 to 12 inches, with less than eight, the distance between the pillar-like members is increased. Therefore, bending is undesirably caused between the pillar-like members when the pins of a probe card is pressed against a wafer placed on chuck top 2. As compared with the integrated structure, if the contact area with chuck top 2 is the same, two interfaces are formed between chuck top 2 and the pillar-like member and between the pillar-like member and the support body to serve as thermal-resistance layers, and therefore, the thermal-resistance layer can be doubled. Thus, the heat generated at chuck top 2 can effectively be insulated. The pillar-like member may be shaped like a cylinder, a triangular prism, a quadrangular prism, a pipe, or any other polygon. Its shape is not specifically limited. In any case, by inserting the pillar-like members in this manner, the heat from chuck top 2 to support body 4 can be blocked.

Preferably, the material of the pillar-like member used as the above-noted heat insulating structure has thermal conductivity of 30 W/mK or less. The thermal conductivity higher than this is not preferable since the heat insulation effect is reduced. The material used for the pillar-like member may include heat-resistant resin such as Si₃N₄, mullite, a mullite-alumina composite, steatite, cordierite, stainless steel, glass (fiber), polyimide, epoxy, or phenol, or a composite thereof.

Preferably, the surface roughness Ra of the contact portion between support body 4 and chuck top 2 or the pillar-like member is 0.1 μm or more. If the surface roughness Ra is less than 0.1 μm, the contact area between support body 4 and chuck top 2 or the pillar-like member increases and in addition, the gap between them becomes relatively small. Therefore, the amount of heat transmission undesirably increases as compared with when Ra is 0.1 μm or more. The upper limit of surface roughness Ra is not specifically limited. However, with surface roughness Ra of 5 μm or more, it may cost much to treat the surface. The method of providing the surface roughness Ra of 0.1 μm or more may include polishing, sandblasting, or the like. In this case, the polishing conditions or sandblasting conditions need to be set properly to control Ra at 0.1 μm or more.

It is noted that in the present invention the surface roughness Ra refers to arithmetic mean roughness Ra defined by JIS B 0601.

Preferably, the surface roughness Ra of the base portion of support body 4 is 0.1 μm or more. As described above, when the surface roughness Ra of the base portion of support body 4 is coarse, the amount of heat transmission to the driving system can be reduced. When the base portion and the cylindrical portion of support body 4 can be separated from each other, the surface roughness Ra of at least one of their contact portions is preferably 0.1 μm or more. If the surface roughness Ra is less than 0.1 μm, the effect of blocking heat from the cylindrical portion to the base portion is reduced. Furthermore, the surface roughness Ra of the contact surface of the pillar-like member with support body 4 and also with chuck top 2 is also preferably 0.1 μm or more. For this pillar-like member, surface roughness Ra is increased similarly, so that the heat transfer to support body 4 can be reduced. As described above, an interface is formed between members, and surface roughness Ra of the interface is 0.1 μm or more, so that the amount of heat transmission to the base portion of support body 4 is reduced, resulting in a reduced amount of power supply to the heating element.

Preferably, the perpendicularity of the outer circumferential portion of the cylindrical portion of support body 4 with respect to the contact surface of the support body 4 with chuck top 2, or of the outer circumferential portion of the cylindrical portion of support body 4 with respect to the contact surface of the pillar-like member with chuck top 2 is 10 mm or less in terms of measurement length 100 mm. For example, if the perpendicularity exceeds 10 mm, undesirably, the cylindrical portion itself is likely to be deformed when the pressure applied from chuck top 2 is applied to the cylindrical portion of support body 4.

It is noted that in the present invention the perpendicularity may be measured, for example, by three-dimensional measurement equipment.

Preferably, a metal layer is formed on the surface of support body 4. An electromagnetic wave produced from the heating element for heating chuck top 2 affects as noise in wafer testing. However, the formation of a metal layer on support body 4 can preferably block this electromagnetic wave. The method of forming a metal layer is not specifically limited. For example, a conductive paste of metal powder such as silver, gold, nickel, or copper with addition of glass frit may be applied by a brush or the like and baked.

Alternatively, a metal such as aluminum or nickel may be formed by thermal spraying. Alternatively, the metal layer may be formed by plating the surface. Alternatively, these methods may be combined. More specifically, plating with a metal such as nickel may be applied after conductive paste is baked, or plating may be formed after thermal spraying. Among these techniques, plating or thermally spraying is especially preferable. Plating is preferable because of high adhesive strength and high reliability. On the other hand, thermal spraying is preferable since the metal film is formed at relatively low costs.

Alternatively, the metal layer may be formed by providing a conductor on at least part of the surface of support body 4. Here, the material to be used is not specifically limited as long as it is conductive. For example, stainless steel, nickel, aluminum, or the like may be used.

The method of providing a conductor may include attaching a ring-shaped conductor to the side surface of support body 4. A metal foil of the above-noted material may be formed in a ring shape having a size larger than the outer diameter of support body 4 and attached to the side surface of support body 4. In addition, a metal foil or a metal plate may be attached to the undersurface portion of support body 4 and connected to the metal foil attached to the side surface, thereby increasing the effect of blocking an electromagnetic wave. Furthermore, using the space inside support body 4, a metal foil or a metal plate may be attached inside the space of the cylinder with a base and connected to the metal foil attached to the side surface and the undersurface, thereby increasing the blocking effect. By employing such a technique, the aforementioned effect can be achieved relatively inexpensively as compared with the application of plating or a conductive paste. A method of fixing a metal foil and a metal plate to support body 4 is not specifically limited. For example, a metal foil and a metal plate may be attached to support body 4 using a metal screw. Preferably, the metal foils and the metal plates at the undersurface portion and the side surface portion of support body 4 are integrated.

In addition, preferably, a support rod is provided in the vicinity of the central portion of support body 4. When a probe card is pressed against chuck top 2, the Support rod can prevent deformation of chuck top 2. Here, the material of the support rod at the central portion is preferably the same as the material of support body 4. Both support body 4 and the support rod thermally expand because they receive heat from the heater body that heats chuck top 2. Here, if the material of support body 4 is different, undesirably, the difference of the thermal expansion coefficient causes unevenness between support body 4 and the support body, so that chuck top 2 is deformed more easily. The size of the support rod is not specifically limited. However, the cross sectional area is preferably 0.1 cm² or more. If the cross sectional area is less than 0.1 cm², undesirably, the supporting effect is not enough and the support rod is more likely to be deformed. Furthermore, the cross sectional area is preferably 100 cm² or less. If the cross sectional area is larger than 100 cm², undesirably, the size of the cooling module inserted into the cylindrical portion of support body 4 is reduced, which will be described later, thereby decreasing the cooling efficiency. The shape of the support rod is not specifically limited, and a cylindrical shape, a triangular prism shape, a quadrangular prism shape, a pipe shape, or the like may be employed. The method of fixing the support rod to support body 4 is also not specifically limited and includes soldering using an active metal, glass sealing, screwing, or the like. Among these, screwing is especially preferable. The screwing facilitates attachment/removal and does not involve a heat treatment in fixing, thereby preventing deformation of support body 4 and the support rod due to the heat treatment.

Preferably, a metal layer is also formed between the heater body heating chuck top 2 and chuck top 2 to block (shield) an electromagnetic wave. This electromagnetic shielding electrode layer serves to block noise caused by an electromagnetic wave or an electric field produced in the heater body or the like, which may affect probing of a wafer. This noise does not have significant impact on the determination of normal electric characteristics but has a considerable impact on the determination of high-frequency characteristics of a wafer. This electromagnetic shielding electrode layer may be formed, for example, by inserting a metal foil between the heater body and the chuck top, where chuck top 2 and the heater body should be insulated. In this case, the metal foil to be used is not specifically limited. However, since the temperature of the heater body becomes approximately 200° C., a foil of stainless steel, nickel, aluminum, or the like is preferable.

The function of the insulating layer between chuck top 2 and the electromagnetic shielding electrode layer is as follows. A capacitor is formed on an electrical circuit between chuck top conductive layer 3 formed on the wafer-placing surface of chuck top 2 and the electromagnetic shielding layer, if chuck top 2 is an insulator, or between chuck top 2 itself and the electromagnetic shielding layer, if chuck top 2 is a conductor. This capacitor component may have an effect as noise during probing of a wafer. Therefore, in order to reduce the effect, an insulating layer is formed between the electromagnetic shielding electrode layer and chuck top 2, thereby reducing the noise.

In addition, a guard electrode layer is preferably provided between chuck top 2 and the electromagnetic shielding electrode layer with an insulating layer interposed therebetween. The guard electrode layer is connected to the metal layer formed on support body 4, so that noise that affects the determination of high-frequency characteristics of a wafer may further be reduced. More specifically, in the present invention, support body 4 including the heating element is entirely covered with a conductor, so that the effect of noise in determination of wafer characteristics in high frequency can be reduced.

Here, the resistance value of the insulating layer between the heater body and the electromagnetic shielding electrode layer, between the electromagnetic shielding electrode layer and the guard electrode layer, between the guard electrode layer and the chuck top is preferably 10⁷Ω or more. If the resistance value is less than 10⁷Ω, minute current flows toward chuck top conductive layer 3 due to the effect from the heater body, which becomes noise during probing and may affect probing. If the resistance value of this insulating layer is 10⁷Ω or more, the above-noted minute current is preferably reduced to such an extent that it does not affect probing. In particular, since circuit patterns formed in a wafer have recently been miniaturized, the aforementioned noise should be reduced as much as possible. Thus, the resistance value of the insulating layer of 10¹⁰Ω or more can result in a more reliable structure.

Furthermore, the dielectric constant of the insulating layer is preferably 10 or less. If the dielectric constant of the insulating layer exceeds 10, undesirably, electric charges are more likely to be accumulated in the electromagnetic shielding layer, the guard electrode layer and chuck top 2 having the insulating layer interposed therebetween, which may cause noise. In particular, since the recent miniaturization of a wafer circuit as described above requires noise reduction, the dielectric constant is preferably 4 or less, and in particular, 2 or less. Preferably, the reduced dielectric constant can reduce the thickness of the insulating layer required to ensure the insulation resistance value or capacitance, thereby reducing thermal resistance by the insulating layer.

If chuck top 2 is an insulator, between chuck top conductive layer 3 and the guard electrode layer and between chuck top conductive layer 3 and the electromagnetic shielding electrode layer, if chuck top 2 is a conductor, between chuck top 2 itself and the guard electrode layer and between chuck top 2 and the electromagnetic shielding electrode layer, the capacitance is preferably 5000 pF or less. If the capacitance exceeds 5000 pF, the effect of the insulating layer as a capacitor is increased, which may affect probing as noise. In particular, considering the recent miniaturization of wafer circuits as described above, the capacitance is preferably 1000 pF or less in order to realize good probing.

As described above, the noise which may affect probing can be reduced significantly by controlling the resistance value, dielectric constant and capacitance of the insulating layer within the ranges as described above. The thickness of this insulating layer is preferably 0.2 mm or more. Essentially, for the reduced size of the device and good heat conduction from the heater body to chuck top 2, a thinner insulating layer is better. However, the thickness of less than 0.2 mm may cause a defect in the insulating layer itself or affect the durability. Ideally, the thickness of the insulating layer is 1 mm or more. The thickness in such an extent is preferable since the durability can be assured and the heat conduction from the heater body is good. Although the upper limit of the thickness is not specifically limited, 10 mm or less is preferable. With the thickness of 10 mm or more, noise is blocked effectively. However, it takes much time for the heat generated in the heater body to conduct to chuck top 2 and the wafer, so that it may become difficult to control the heating temperature. The thickness is preferably 5 mm or less, although depending on the probing conditions, since the temperature control may become relatively easy.

Although not specifically limited, the thermal conductivity of the insulating layer is preferably 0.5 W/mK or more in order to realize good heat conduction from the heater body as described above. If 1 W/mK or more, preferably, the heat transmission becomes better.

The specific material of the insulating layer is not specifically limited as long as it satisfies the characteristics as described above and has heat resistance such that it can endure the probing temperature. Ceramic or resin may be employed. Among these, the resin to be used preferably may be, for example, silicone resin, the resin with a filler dispersed therein, ceramic such as alumina, or the like. The filler dispersed in resin serves to increase heat conduction of silicone resin. The material is not specifically limited as long as it is not reactive with the resin, and may include, for example, boron nitride, aluminum nitride, alumina, or silica.

The region in which the insulating layer is formed is preferably equivalent to or larger than the region in which the electromagnetic shielding electrode layer, the guard electrode layer or the heater body is formed. If the formation region is small, undesirably, noise may intrude from the portion that is not covered with the insulating layer.

Description will be made below with reference to an example. For example, silicone resin including boron nitride dispersed therein is used as the insulating layer. The dielectric constant of this material is 2. When the silicone resin including boron nitride dispersed therein is sandwiched as an insulating layer between the electromagnetic shielding electrode layer and the guard electrode layer, between the guard electrode layer and the chuck top, the diameter may be 300 mm, if the chuck top corresponds to a 12-inch wafer. Here, if the thickness of the insulating layer is 0.25 mm, the capacitance can be 5000 pF. If the thickness is 1.25 mm or more, the capacitance can be 1000 pF. Since the volume resistivity of this material is 9×10¹⁵Ω cm, the resistance value can be about 1×10¹²Ω with a diameter of 300 mm and a thickness of 0.8 mm or more. Furthermore, since this material has thermal conductivity of about 5 W/mK, if the thickness, which can be selected depending on the conditions of probing, is 1.25 mm or more, both the capacitance and the resistance value can be adequate.

Preferably, a through hole through which an electrode for supplying power to the heater body or an electromagnetic shielding electrode layer is inserted is formed in the cylindrical portion of support body 4. Here, in particular, the through hole is preferably formed in the vicinity of the central portion of cylindrical portion 41 of support body 4. If the through hole is formed close to the outer circumferential portion, the strength of the support body which is provided by the circumferential portion of support body 4 is reduced due to the effect of the pressure of the probe card, so that support body 4 is undesirably deformed in proximity to the through hole.

If the warping of chuck top 2 is 30 μm or more, the needle of the prober is in improper contact during probing, so that the characteristics cannot be evaluated or a failure determination is made due to poor contact. Undesirably, the yields are reduced due to unduly poor evaluation. On the other hand, it is not preferable that the parallelism between the surface of chuck conductive layer 3 and the undersurface of the base portion of support body 4 is 30 μm or more, because poor contact may take place similarly. Even if the warping of chuck top 2 and the parallelism are as good as 30 μm or less at room temperature, it is not preferable if the warping and the parallelism are 30 μm or more during probing at 200° C. The same applies to probing at −70° C. In other words, it is preferable that both of the warping and the parallelism are 30 μm or less throughout the temperature range for probing.

It is noted that the warping and parallelism as described above can be measured by measurement equipment such as three-dimensional measurement equipment.

Chuck top conductive layer 3 is formed on the wafer-placing surface of chuck top 2. Chuck top conductive layer 3 is formed to serve to protect chuck top 2 from corrosive gas, acid or alkaline chemicals, organic solvent or water that are usually used in semiconductor manufacturing and to serve to establish a ground in order to block electromagnetic noise from below chuck top 2 to a wafer placed on chuck top 2.

The method of forming chuck top conductive layer 3 is not specifically limited and may include applying a conductive paste by screen printing followed by baking, vapor deposition or sputtering, thermal spraying or plating, or the like. Of these techniques, thermal spraying and plating are especially preferable. These techniques do not involve a heat treatment in forming chuck top conductive layer 3 and thus do not cause warp in chuck top 2 itself, which would be caused by the heat treatment. In addition, because of relatively low costs, chuck top conductive layer 3 that is inexpensive and has excellent characteristics can be formed. In particular, preferably, chuck top conductive layer 3 is fabricated by forming a thermal sprayed film on chuck top 2 by thermal spraying and forming a plating film on the thermal sprayed film by plating. The thermal sprayed film formed by thermal spraying is superior to the plating film formed by plating in adhesiveness with ceramic or metal-ceramic composite. This is because the sprayed material, for example, aluminum, nickel or the like produces some amount of oxide, nitride or oxynitride during thermal spraying, and the produced compound reacts with the surface layer of chuck top 2 and strongly adheres thereto.

However, since the sprayed film includes these compounds, the conductivity of the film becomes low. By contrast, the plating can form almost pure metal, so that chuck top conductive layer 3 excellent in conductivity can be formed although the adhesive strength with chuck top 2 is not so high as a thermal sprayed film. Therefore, when a thermal sprayed film is underlaid and a plating film is formed thereon, preferably, the plating film has good adhesive strength with the thermal sprayed film, which is a metal, and also provides good electric conductivity.

Preferably, surface roughness Ra of chuck top conductive layer 3 on chuck top 2 is 0.1 μm or less. If surface roughness Ra exceeds 0.1 μm, in determination of a device generating a large amount of heat, the heat generated by self-heating of the device itself cannot be dissipated from chuck top 2 during probing, thereby increasing the temperature of the device itself and possibly resulting in thermal breakdown. Surface roughness Ra of 0.02 μm or less is preferable in that heat can be dissipated more efficiently.

When the heating element for chuck top 2 is heated for probing, for example, at 200° C., the temperature of the lower surface of support body 4 is preferably 100° C. or lower. If the temperature exceeds 100° C., the driving system for the prober provided below support body 4 is distorted due to the thermal expansion coefficient difference and is thus degraded in accuracy, thereby causing inconvenience such as misalignment in probing or improper contact of the probe due to warping and reduced parallelism. Accordingly, device evaluation cannot be made properly. In addition, when the determination is conducted at the temperature increased to 200° C. followed by determination at room temperature, it takes much time to cool from 200° C. to room temperature, thereby degrading throughput.

Preferably, Young's modulus of chuck top 2 is 250 GPa or more. If Young's modulus is less than 250 GPa, the load applied to chuck top 2 during probing causes bending of chuck top 2, thereby significantly deteriorating the flatness and parallelism of the upper surface of chuck top 2. Therefore, poor contact of probe pins is caused to make accurate testing impossible. Moreover, wafers may be broken. Therefore, Young's modulus of chuck top 2 is preferably 250 GPa or more, more preferably 300 GPa or more.

Preferably, the thermal conductivity of chuck top 2 is 15 W/mK or more. If less than 15 W/mK, undesirably, the temperature distribution of a wafer placed on chuck top 2 becomes worse. Therefore, if the thermal conductivity is 15 W/mK or more, such thermal uniformity can be obtained that is acceptable to probing. The material having such thermal conductivity may include alumina at a purity of 99.5% (thermal conductivity 30 W/mK). More preferably, the thermal conductivity is 170 W/mK or more. The material having such thermal conductivity may include aluminum nitride (170 W/mK), Si-SiC composite (170 W/mK to 220 W/mK), or the like. With the thermal conductivity in such an extent, chuck top 2 can be excellent in thermal uniformity.

Preferably, the thickness of chuck top 2 is 8 mm or more. If the thickness is less than 8 mm, the load applied to chuck top 2 during probing causes bending of chuck top 2, thereby significantly deteriorating the flatness and parallelism of the upper surface of chuck top 2. Thus, because of the poor contact of the probe pin, accurate testing becomes impossible. In addition, wafers may be broken. Therefore, the thickness of chuck top 2 is preferably 8 mm or more, more preferably 10 mm or more.

The material that forms chuck top 2 is preferably a metal-ceramic composite, ceramic or metal. Here, a metal-ceramic composite is preferably a composite of aluminum and silicon carbide or a composite of silicon and silicon carbide. Among these, especially, a composite of silicon and silicon carbide is preferable because of high Young's modulus and high thermal conductivity.

Furthermore, since these composite materials are conductive, the heating element can be formed, for example, by forming an insulating layer on the surface opposite to the wafer-placing surface by thermal spraying, screen printing or any other technique and screen-printing a conductive layer thereon or forming a conductive layer in a prescribed pattern by vapor deposition or any other technique.

Alternatively, the heating element can also be formed by forming a metal foil made of stainless steel, nickel, silver, molybdenum, tungsten, chrome, or an alloy thereof in a prescribed heating element pattern by etching. In this technique, the insulation from chuck top 2 can be formed by the similar technique as described above. Alternatively, for example, an insulative sheet may be inserted between chuck top 2 and the heating element. In this case, preferably, an insulating layer can be formed remarkably cheaply and easily as compared with the above-noted technique. The resin to be used in this case includes a mica sheet, epoxy resin, polyimide resin, phenol resin, silicone resin or the like in view of heat resistance. Among those, especially mica is preferable. The reason is that mica is excellent in heat resistance and electric insulation, easily processed, and moreover cheap.

Ceramic as a material of chuck top 2 is relatively usable since it does not require formation of an insulating layer as described above. In this case, the method of forming a heating element can be selected from the similar techniques as described above. Among the ceramic materials, alumina, aluminum nitride, silicon nitride, mullite, or an alumina and mullite composite is preferable. These materials are especially preferable since they have relatively high Young's modulus, thereby reducing deformation caused by pressing a probe card. Among them, alumina is most excellent because of relatively low costs and excellent electric characteristics at high temperature. In particular, alumina at purity of 99.6% or more has high insulation property at high temperature. More preferably, the purity is 99.9% or more. More specifically, silicon oxides, alkaline-earth metal oxides, or the like are added to alumina in order to reduce the sintering temperature when a substrate is sintered. This reduces the electric characteristics of pure alumina, such as electrical insulation at high temperature. Therefore, the purity is preferably 99.6% or more, more preferably 99.9% or more.

Alternatively, a metal may also be employed as a material of chuck top 2. In this case, tungsten, molybdenum, or an alloy thereof may be used, which have high Young's modulus. Specifically, the alloy includes a tungsten and copper alloy or a molybdenum and copper alloy. These alloys can be prepared by impregnating copper in tungsten or molybdenum. Since these metals are conductive similar to the aforementioned ceramic-metal composite, chuck top 2 can be used by applying the technique as described above as it is to form a chuck top conductive layer and form a heating element.

When a load of 3.1 MPa is applied to chuck top 2, the amount of bending thereof is preferably 30 μm or less. A number of pins for testing a wafer are pressed against a wafer from a probe card, so that that pressure may also affect chuck top 2 causing some bending of chuck top 2. Here, if the amount of bending exceeds 30 μm, undesirably the pins of the probe card cannot press a wafer uniformly, so that wafer testing may become impossible. More preferably, the amount of bending with application of the pressure is 10 μm or less.

In the present invention, cooling mechanism 6 may be provided in the cylindrical portion of support body 4. Cooling mechanism 6 can cool chuck top 2 rapidly by removing the heat when the necessity to cool chuck top 2 arises. When chuck top 2 is heated, cooling mechanism 6 is separated from chuck top 2 in order to increase the temperature efficiently. Therefore, cooling mechanism 6 is preferably movable. The technique of making cooling mechanism 6 movable uses elevator means such as an air cylinder. A through hole through which a screw passes has to be formed in cooling mechanism 6. In this way, preferably, the speed of cooling chuck top 2 can be improved greatly and throughput can be increased. In this technique, the pressure of the probe card in probing is not applied to the cooling module at all, so that the cooling module is free from deformation caused by the pressure. In addition, preferably, the cooling ability is higher as compared with air cooling.

When the speed of cooling chuck top 2 is a higher priority, cooling mechanism 6 may be fixed to chuck top 2. As a manner of fixing, a heater body having a structure including a resistance heating element sandwiched between insulators is installed opposite to the wafer-placing surface of chuck top 2, and the cooling mechanism may be fixed on the underside of the heater body. As another embodiment, cooling mechanism 6 is installed directly on the side opposite to the wafer-placing surface of chuck top 2, and a heater body having a structure including a resistance heating element sandwiched between insulators is fixed to the underside of cooling mechanism 6. Here, a soft material having deformability and heat resistance and having high thermal conductivity can be inserted between the side opposite to the wafer-placing surface of chuck top 2 and cooling mechanism 6. The inclusion of the soft material that achieves the flatness and alleviates warpage between chuck top 2 and the cooling mechanism can increase the contact area and enhance the original cooling ability of the cooling module, thereby increasing the cooling speed.

In any of the techniques, the fixing method is not specifically limited. For example, a mechanical technique such as screwing or clamping may be employed. When chuck top 2 and the cooling module and the insulation heater are fixed by screwing, the number of screws is three or more, preferably six or more, so that the contact therebetween is enhanced thereby further improving the ability of cooling chuck top 2.

Furthermore, in this structure, cooling mechanism 6 may be mounted in the cavity of support body 4, or cooling mechanism 6 may be mounted on support body 4 and chuck top 2 may be mounted thereon. In any method, chuck top 2 and cooling mechanism 6 are fixed to each other, so that the cooling speed can be increased as compared with the movable structure. In addition, since the cooling mechanism portion is mounted at the support body portion, the contact area of cooling mechanism 6 with chuck top 2 is increased thereby cooling chuck top 2 more quickly.

In this way, when cooling mechanism 6 is fixed to chuck top 2, the temperature may be increased without feeding refrigerant into cooling mechanism 6. In this case, since no refrigerant flows in cooling mechanism 6, the heat generated in the heating element is not removed by refrigerant and does not escape to the outside of the system. Therefore, the temperature can be increased more efficiently. However, also in this case, refrigerant is fed into cooling mechanism 6 in cooling, so that chuck top 2 can be cooled efficiently.

Furthermore, chuck top 2 and cooling mechanism 6 may be integrated. In this case, the material used for chuck top 2 and cooling mechanism 6 to be integrated is not specifically limited. However, since a channel for refrigerant to flow needs to be formed in cooling mechanism 6, the thermal expansion coefficient difference between the chuck top portion and the cooling mechanism portion is preferably small. As a matter of course, the same material is preferable.

The material to be used in this case may include ceramic or a composite of ceramic and metal as described above as the material of chuck top 2. In this case, the wafer holder may be fabricated by forming chuck top conductive layer 3 on the wafer-placing surface side, forming a channel for cooling on the opposite side, and in addition, integrating a substrate made of the same material as chuck top 2, for example, by a technique such as soldering or glass sealing. As a matter of course, a channel may be formed on the substrate side to be affixed or channels may be formed in both substrates. Integration using screwing is also possible.

In this manner, chuck top 2 and cooling mechanism 6 are integrated, so that chuck top 2 can be cooled more quickly than when cooling mechanism 6 is fixed to chuck top 2 as described above.

In this technique, a metal can also be used as a material of the integrated chuck top 2. Since metal is easily processed and inexpensive as compared with ceramic or a composite of ceramic and metal as described above, a channel for refrigerant can be easily formed. However, when a metal is used for the integrated chuck top 2, the pressure applied in probing may cause bending. Therefore, bending can be prevented by providing an anti-chuck top-deformation substrate on the side opposite to the wafer-placing surface of the integrated chuck top 2.

A substrate having Young's modulus of 250 GPa or more is preferably used as an anti-chuck top-deformation substrate. This anti-chuck top-deformation substrate may be housed in the cavity formed in support body 4 or the anti-chuck top-deformation substrate may be inserted between integrated chuck top 2 and support body 4. This anti-chuck top-deformation substrate may be fixed to the integrated chuck top by a mechanical technique such as screwing as described above or may be fixed by a technique such as soldering or glass sealing. Similarly to when the cooling module is fixed to chuck top 2, preferably, no refrigerant is fed when the temperature of chuck top 2 is increased or kept high, and refrigerant is fed during cooling, thereby increasing and decreasing the temperature more efficiently.

In the present embodiment where the material of chuck top 2 is metal, for example, chuck top conductive layer 3 may be formed anew on the surface of the wafer-placing surface, for example, when the material of chuck top 2 easily causes oxidation or degradation of the surface or does not have high electrical conductivity. In this technique, as described above, chuck top conductive layer 3 may be formed by plating having oxidation resistance such as nickel or a combination with thermal spraying, and the surface of the wafer-placing surface may be polished.

Also in this structure, an electromagnetic shielding layer or a guard electrode layer may be formed as described above as necessary. In this case, the insulated heating element is covered with metal as described above, a guard electrode layer is formed with an insulating layer interposed, and an insulating layer is formed between the guard electrode layer and chuck top 2. Additionally, the anti-chuck top-deformation substrate may be fixed integrally to chuck top 2.

In this structure, as a method of installing chuck top 2 integrated with cooling mechanism 6 on support body 4, the cooling mechanism portion may be installed in the cavity portion formed by support body 4. Alternatively, similarly to when chuck top 2 and cooling mechanism 6 are fixed by screwing, the cooling module portion is used for installation on support body 4.

The material of cooling mechanism 6 is not specifically limited. Preferably, aluminum or copper and an alloy thereof are used since the heat of chuck top 2 can be removed rapidly because of relatively high thermal conductivity. Alternatively, stainless steel, magnesium alloy, nickel, or any other metal material may be used. Additionally, a metal film having oxidation resistance such as nickel, gold or silver may be formed using a technique such as plating or thermal spraying in order to render the cooling module oxidation-resistant.

Ceramic may be used as a material of cooling mechanism 6. The material in this case is not specifically limited. Aluminum nitride or silicon carbide is preferable since heat can be removed from chuck top 2 quickly because of relatively high thermal conductivity. Furthermore, silicon nitride or aluminum oxynitride is preferable because of high mechanical strength and high durability. Ceramic oxide such as alumina, cordierite or steatite is preferable since it is relatively cheap. As described above, a variety of materials can be selected for cooling mechanism 6 and thus, a material may be selected depending on a purpose. Among those, aluminum with nickel plating or copper with nickel plating is especially preferable because of high oxidation resistance, high thermal conductivity, and relatively low costs.

Refrigerant may be fed inside this cooling mechanism 6. In this manner, the heat transmitted from the heater body to cooling mechanism 6 can be removed from the cooling module quickly, so that preferably, the speed of cooling the heater body can be further improved.

As a suitable example, two aluminum plates are prepared, and a channel in which water flows is formed in one of the aluminum plates by machining or the like. Then, in order to improve corrosion resistance and oxidation resistance, nickel plating is applied on the front surface. Then, the other aluminum plate with nickel plating is affixed. Here, for example, an O-ring or the like is inserted around the channel in order to prevent water leakage. Then, the two aluminum plates are affixed to each other by screwing or welding.

Alternatively, two copper (oxygen-free copper) plates are prepared, and a channel in which water flows is formed in one of the copper plates by machining or the like. The other copper plate and a stainless steel pipe for inlet/outlet of refrigerant are joined at the same time by soldering. The cooling plates are nickel plated on the entire surface thereof in order to improve corrosion resistance and oxidation resistance of the joined cooling plates. Alternatively, in the another embodiment, a pipe in which refrigerant flows may be attached to a cooling plate such as an aluminum plate or copper plate, resulting in a cooling mechanism. In this case, a spot-face having a shape close to the cross sectional shape of the pipe may be formed in the cooling plate and is brought into close contact with the pipe, thereby further improving the cooling efficiency. Alternatively, in order to improve the contact of the cooling plate with the cooling pipe, thermal conductive resin, ceramic or the like may be inserted as an interposing layer.

In a different form, a pipe in which refrigerant can be fed may be fixed to aluminum or copper to form a cooling mechanism. In this case, in order to secure the contact area between the pipe and aluminum or copper, a groove having approximately the same shape as the cross sectional shape of the cooling pipe may be provided in the metal plate made of aluminum, copper or the like, or a material having deformability such as resin may be sandwiched between the metal plate and the pipe. On the contrary, a planar shape may be formed as a part of the cross sectional shape of the pipe to be fixed to the metal plate. The method of fixing the metal plate and the pipe may include screwing using a metal band or the like, or welding or soldering, as a matter of course.

Furthermore, the refrigerant fed into such cooling modules may be, for example, liquid such as Fluorinert, Galden or water or gas such as nitrogen, air or helium. Here, the refrigerant to be fed is not specifically limited and may be selected depending on a purpose.

In the embodiment, a wafer holder for a wafer prober has been described as an exemplary wafer holder. However, the present invention is not limited thereto. Wafer holder 1 in accordance with the present invention may suitably be used for heating and testing a process target such as a wafer. For example, suitably, the present invention may be applied to a wafer prober, a handler or a tester because it is possible to take advantage of the characteristics such as high stiffness and high thermal conductivity. In particular, the wafer holder in accordance with the present invention is preferably applied as a holder for a wafer prober.

The heater unit in accordance with the present invention includes wafer holder 1 as described above and a known constituent member, and includes, for example, wafer holder 1, the heater body described above and a power supply to operate the heater body. The heater unit for a wafer prober heats a process target such as a semiconductor wafer.

The wafer prober in accordance with the present invention includes the heater unit as described above and a known constituent member and includes, for example, the heater unit as described above, a driver for driving the heater unit in the X, Y, Z directions, and a wafer transfer device. The wafer prober may additionally include a probe card and the like.

### EXAMPLE

Si-SiC substrate having a diameter of 310 mm and a thickness of 15 mm was prepared. A concentrically-arranged groove for vacuum-chucking a wafer and a through hole were formed in the wafer-placing surface of the substrate, and the wafer-placing surface was nickel plated to form a chuck top conductive layer Thereafter, the chuck top conductive layer was polished, resulting in a chuck top having the amount of warping of 10 μm as a whole and surface roughness Ra of 0.02 μm.

Then, a cylindrical-shaped mullite-alumina composite having a diameter of 310 mm and a thickness of 40 mm was prepared as a support body. A spot-face having an inner diameter of 285 mm and a depth of 20 mm was provided in the support body. In addition, six through holes each having a diameter of 6 mm were formed at the central portion and at the circumferential positions of a circle having a diameter of 220 mm (PCD 220).

Then, as a cooling mechanism, a channel having a radius of 4 mm was formed in a copper plate having a thickness of 8 mm, and a copper plate having a thickness of 2 mm was jointed thereon by a solder material. Then, nickel plating was applied, resulting in a cooling mechanism. Then, in order to attach this cooling mechanism to the chuck top, eight through holes each having a diameter of 6 mm were formed at the circumferential positions of a circle having a diameter of 180 mm (PCD 180).

Then, M4 screw holes were respectively formed in the chuck top for fixing the support body and for fixing the cooling mechanism. Then, each of the screws made of materials shown in Nos. 3-9 in Table 1 as illustrated below were inserted to a screw hole, so that the chuck top, the support body and the cooling mechanism were fixed by screwing. In addition, the one having dimethaycrylate ester resin inserted in the screw hole and the one without the same were prepared.

Furthermore, a heating element sandwiched between micas was attached to the cooling mechanism. The heating element was formed by etching a stainless steel foil in a prescribed pattern. A through hole for connecting an electrode for supplying power to the heating element was formed in the support body. Metal layers were then formed on the side surface and the undersurface of the support body by thermally spraying aluminum.

A wafer was heated at 200° C. by supplying power to the heating element of the wafer holder for a wafer prober as described above. Thereafter, power supply to the heating element was stopped, and nitrogen at room temperature was fed into the channel of the cooling mechanism to cool the wafer to 60° C. Thereafter, nitrogen supply was stopped, and the heating element was powered, so that the temperature of the wafer is increased to 200° C. This test was conducted ten times.

TABLE 1

| | | thermal expansion |
|---|---|---|
| | | coefficient |
| | material | (×10⁻⁶/K)) |
| No. 1 | Si—SiC | 2.8 |
| No. 2 | mullite-alumina composite | 4.5 |
| No. 3 | Kovar | 5.0 |
| No. 4 | copper | 17 |
| No. 5 | stainless steel | 16 |
| No. 6 | tungsten | 4.5 |
| No. 7 | Alloy909 | 7.8 |
| No. 8 | nickel | 14 |
| No. 9 | aluminum | 20 |

It is noted that the thermal expansion coefficient in Table 1 was measured by a laser interferometric method.

As for the screw for fixing the chuck top and the cooling mechanism, no problem was found in stainless steel, Kovar, tungsten, nickel, and copper having a thermal expansion coefficient between the thermal expansion coefficient of the chuck top (2.8×10⁻⁶/K) and the thermal expansion coefficient of the cooling mechanism (17×10⁻⁶/K). However, in aluminum, the fixing between the chuck top and the cooling mechanism became loose, thereby reducing the cooling ability.

On the other hand, as for the screw for fixing the chuck top and the support body, Kovar, tungsten, and Alloy 909 could be used without any problem where a difference of thermal expansion coefficient from the chuck top was 5.0×10⁻⁶/K or less. However, in the other metals, the screw hole portion of the chuck top was broken or the screw itself was deformed.

In accordance with the present invention, the support body and the chuck top as well as the cooling mechanism and the chuck top can be fixed to each other reliably. Therefore, it is possible to provide a wafer holder for a wafer prober with high throughput.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A wafer holder comprising a chuck top having a chuck top conductive layer on a surface thereof and a support body supporting said chuck top, wherein said chuck top and said support body are fixed to each other by a screw, and a difference of thermal expansion coefficient between said screw and said chuck top is at most 5.0×10⁻⁶/K.

2. The wafer holder according to claim 1, wherein said screw is arranged in the form of a concentric circle including a central portion of said chuck top.

3. The wafer holder according to claim 1, wherein said screw is fixed in a screw hole formed in said chuck top using heat resistant resin.

4. A heater unit for a wafer prober comprising the wafer holder according to claim 1.

5. A wafer prober comprising the heater unit according to claim 4.

6. A wafer holder comprising a chuck top having a chuck top conductive layer on a surface thereof, a support body supporting said chuck top, and a cooling mechanism for cooling said chuck top, wherein said chuck top and said support body and said cooling mechanism are fixed to each other by a screw, wherein a thermal expansion coefficient of said screw is between a thermal expansion coefficient of said chuck top and a thermal expansion coefficient of said cooling mechanism.

7. The wafer holder according to claim 6, wherein said screw is arranged in the form of a concentric circle including a central portion of said chuck top.

8. The wafer holder according to claim 6, wherein said screw is fixed in a screw hole formed in said chuck top using heat resistant resin.

9. A heater unit for a wafer prober comprising the wafer holder for a wafer prober according to claim 6.

10. A wafer prober comprising the heater unit according to claim 9.
